(19) United States
(12) Patent Application Publication
(10) Pub. No.: US 2026/0262513 A1
(43) Pub. Date: Sep. 3, 2026

(54) MULTI-LAYER SUBSTRATE, ELECTRONIC DEVICE INCLUDING SAME, AND METHOD FOR MANUFACTURING MULTI-LAYER SUBSTRATE

(71) Applicant: STEMCO CO., LTD., Cheongju-si (KR)

(72) Inventor: Sung Jin LEE, Cheongju-si (KR)

(73) Assignee: STEMCO CO., LTD., Cheongju-si (KR)

(21) Appl. No.: 19/655,841

(22) Filed: Apr. 23, 2026

Related U.S. Application Data
(63) Continuation of application No. PCT/KR2024/015960, filed on Oct. 21, 2024.

(30) Foreign Application Priority Data
Dec. 22, 2023 (KR) 10-2023-0189240

(51) Int. Cl. H10W 70/63; H10W 70/05

(52) U.S. Cl. CPC H10W 70/63; H10W 70/095

(57) ABSTRACT

A multilayer substrate in which, when a via is formed in the multilayer substrate, a sub-via is formed to partially overlap a main via to mitigate an undercut level inside the via, a method of manufacturing the multilayer substrate, and an electronic device including the multilayer substrate are provided. The multilayer substrate includes: a base substrate; a first circuit wiring layer and a first via pad formed on the base substrate; an interlayer insulating layer covering the first circuit wiring layer and the first via pad; a via portion formed to penetrate the interlayer insulating layer and contact the first via pad; a plating portion filling the via portion; a second circuit wiring layer formed on the interlayer insulating layer; and a second via pad formed on the plating portion, wherein the via portion includes a main via and a sub-via partially overlapping the main via.

### CROSS-REFERENCE TO RELATED APPLICATION

This application is a Continuation of International Application No. PCT/KR 2024/015960 filed on Oct. 21, 2024, which claims priority from Korean Patent Application No. 10-2023-0189240 filed on Dec. 22, 2023 in the Korean Intellectual Property Office, and all the benefits accruing therefrom under 35 U.S.C. 119, the contents of which in its entirety are herein incorporated by reference.

### BACKGROUND

### 1. TECHNICAL FIELD

The present disclosure relates to a multilayer substrate applicable to a flexible circuit board or a coil substrate, a method of manufacturing the multilayer substrate, and an electronic device including the multilayer substrate.

### 2. Description of the Related Art

A via may be formed in a multilayer substrate according to the following sequence. First, a first-layer circuit pattern and a lower via pad are formed on a base substrate, and an interlayer insulating layer is applied thereon. Thereafter, the interlayer insulating layer applied on the lower via pad is laser-processed, thereby forming a via hole. Subsequently, carbides generated during the laser processing are removed through a desmear process or an etching process. Thereafter, in order to fill an undercut structure generated when a portion of an upper surface of the lower via pad that is in contact with an inner side of the interlayer insulating layer is etched, a nickel/chromium (Ni/Cr) base layer is formed on an upper surface and an inner side of the interlayer insulating layer and on the upper surface of the lower via pad. Thereafter, a resist pattern for forming a second-layer circuit pattern is formed on the interlayer insulating layer. Subsequently, spaces between such resist patterns and inside the via hole are plated.

However, when the via is formed according to the above-described sequence, the Ni/Cr base layer is formed on the lower via pad including copper (Cu), the via hole is filled with Cu again on the Ni/Cr base layer, and an upper via pad may be formed thereon. Accordingly, dissimilar metal layers of Cu and Ni/Cr may be formed inside the via hole, which may weaken the bonding strength between the metals and reduce via interface reliability.

Meanwhile, in order to form a homogeneous metal layer composed only of Cu inside the via hole, a thickness at which the undercut structure is formed may be increased by strengthening a desmear level or an etching level. However, when the via is formed according to such a method, it may be difficult to apply current to a lower portion or an inner side of the undercut structure during a plating process. As a result, a void region in which Cu is not filled may occur inside the via hole. This may act as a factor causing separation at the via interface and consequently reduce via interface reliability.

### SUMMARY

A technical problem to be addressed by the present disclosure is to provide a method of manufacturing a multilayer substrate, a multilayer substrate manufactured according to the method, and an electronic device including the multilayer substrate, in which, when forming a via in the multilayer substrate, a sub-via is formed to partially overlap a main via to mitigate an undercut level inside the via.

The technical problems of the present disclosure are not limited to that described above, and other technical problems not mentioned herein may be clearly understood by one of ordinary skill in the art from the following description.

An aspect of a multilayer substrate of the present disclosure for achieving the above technical problems includes: a base substrate; a first circuit wiring layer and a first via pad formed on the base substrate; an interlayer insulating layer covering the first circuit wiring layer and the first via pad; a via portion formed to penetrate the interlayer insulating layer and contact the first via pad; a plating portion filling the via portion; a second circuit wiring layer formed on the interlayer insulating layer; and a second via pad formed on the plating portion, wherein the via portion includes a main via and a sub-via partially overlapping the main via.

An aspect of an electronic device of the present disclosure for achieving the above technical problems includes the multilayer substrate.

An aspect of a method of manufacturing a multilayer substrate of the present disclosure for achieving the above technical problems includes: forming a first circuit wiring layer and a first via pad on a base substrate; forming an interlayer insulating layer to cover the first circuit wiring layer and the first via pad; forming a main via to penetrate a surface of the interlayer insulating layer and contact the first via pad; forming a sub-via partially overlapping the main via; performing an etching process or a desmear process on the main via and the sub-via; forming a base layer to cover the interlayer insulating layer, the main via, and the sub-via; and forming a plating portion in the main via and forming a second circuit wiring layer and a second via pad on the interlayer insulating layer and the plating portion.

Specific details of other embodiments are included in the detailed description and the drawings.

According to the present disclosure, the following effects may be obtained by forming a sub-via to partially overlap a main via so as to mitigate the undercut level inside the via.

First, a stable conductive state between a via wall and an inner-layer pad may be maintained, and current may be simultaneously applied to the via wall and the inner-layer pad during electrolytic copper plating to deposit copper. Accordingly, the possibility of void generation may be suppressed.

Second, after via processing, a separation distance between the via, a via pad, and an insulating layer may be controlled. Accordingly, interface reliability between the via and the via pad may be secured.

Third, in order to prevent degradation of via interface reliability, a homogeneous metal layer may be formed in the via hole. Accordingly, bonding strength between homogeneous metals may be improved.

The effects of the present disclosure are not limited to those described above, and other effects not mentioned herein may be clearly understood by those skilled in the art from the following description.

### BRIEF DESCRIPTION OF THE DRAWINGS

FIG. 1 is a flowchart illustrating a method of manufacturing a multilayer substrate according to an embodiment of the present disclosure.

FIG. 2 is an exemplary view illustrating step S110 of the method of manufacturing a multilayer substrate according to an embodiment of the present disclosure.

FIG. 3 is an exemplary view illustrating step S120 of the method of manufacturing a multilayer substrate according to an embodiment of the present disclosure.

FIG. 4 is an exemplary view illustrating step S130 of the method of manufacturing a multilayer substrate according to an embodiment of the present disclosure.

FIG. 5 is an exemplary view illustrating step S140 of the method of manufacturing a multilayer substrate according to an embodiment of the present disclosure.

FIG. 6 is a first exemplary view illustrating step S150 of the method of manufacturing a multilayer substrate according to an embodiment of the present disclosure.

FIG. 7 is a second exemplary view illustrating step S150 of the method of manufacturing a multilayer substrate according to an embodiment of the present disclosure.

FIG. 8 is a third exemplary view illustrating step S150 of the method of manufacturing a multilayer substrate according to an embodiment of the present disclosure.

FIG. 9 is a fourth exemplary view illustrating step S150 of the method of manufacturing a multilayer substrate according to an embodiment of the present disclosure.

FIG. 10 is an exemplary view illustrating step S160 of the method of manufacturing a multilayer substrate according to an embodiment of the present disclosure.

FIG. 11 is an exemplary view illustrating step S180 of the method of manufacturing a multilayer substrate according to an embodiment of the present disclosure.

FIG. 12 is a first exemplary view illustrating step S190 of the method of manufacturing a multilayer substrate according to an embodiment of the present disclosure.

FIG. 13 is a second exemplary view illustrating step S190 of the method of manufacturing a multilayer substrate according to an embodiment of the present disclosure.

FIG. 14 is a flowchart illustrating a method of manufacturing a multilayer substrate according to another embodiment of the present disclosure.

FIG. 15 is an exemplary view illustrating step S430 of the method of manufacturing a multilayer substrate according to another embodiment of the present disclosure.

FIG. 16 is a first exemplary view illustrating step S440 of the method of manufacturing a multilayer substrate according to another embodiment of the present disclosure.

FIG. 17 is a second exemplary view illustrating step S440 of the method of manufacturing a multilayer substrate according to another embodiment of the present disclosure.

FIG. 18 is a third exemplary view illustrating step S440 of the method of manufacturing a multilayer substrate according to another embodiment of the present disclosure.

FIG. 19 is a fourth exemplary view illustrating step S440 of the method of manufacturing a multilayer substrate according to another embodiment of the present disclosure.

### DETAILED DESCRIPTION

Hereinafter, embodiments of the present disclosure will be described in detail with reference to the accompanying drawings. The same reference numerals are used to denote the same components in the drawings, and redundant descriptions thereof will be omitted.

A multilayer substrate of the present disclosure may suppress the possibility of void generation, improve bonding strength between homogeneous metals, and improve via interface reliability by forming a sub-via to partially overlap a main via to mitigate an undercut level inside the via. Hereinafter, a method of manufacturing the multilayer substrate will be described.

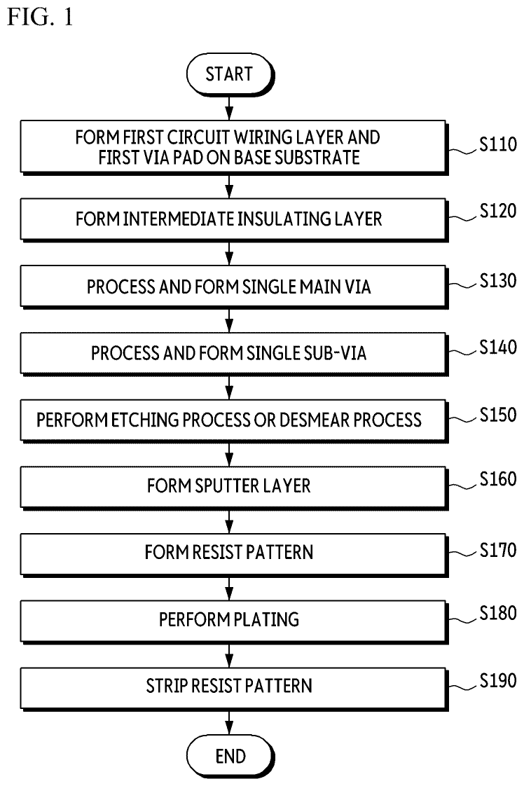

FIG. 1 is a flowchart illustrating a method of manufacturing a multilayer substrate according to an embodiment of the present disclosure.

First, a first circuit wiring layer and a first via pad are formed on one surface of a base substrate (S110).

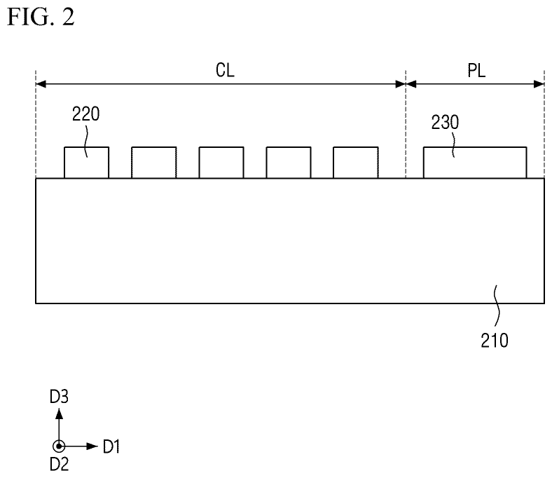

FIG. 2 is an exemplary view illustrating step S110 of the method of manufacturing a multilayer substrate according to an embodiment of the present disclosure. A first direction D1 and a second direction D2 constitute a plane in a horizontal direction. For example, the first direction D1 may be a front-rear direction, and the second direction D2 may be a left-right direction. Alternatively, the first direction D1 may be a left-right direction, and the second direction D2 may be a front-rear direction. A third direction D3 is a height direction and is a direction perpendicular to the plane defined by the first direction D1 and the second direction D2. The third direction D3 may be an up-down direction.

Referring to FIG. 2, a first circuit wiring layer 220 may be formed on a wiring region CL of a base substrate 210, and a first via pad 230 may be formed on a pad region PL of the base substrate 210. The first circuit wiring layer 220 and the first via pad 230 may be formed simultaneously. However, the present disclosure is not limited thereto, and the first circuit wiring layer 220 and the first via pad 230 may also be formed at different times. In addition, the first circuit wiring layer 220 and the first via pad 230 may be formed of the same metal, but may also be formed of different metals.

The first circuit wiring layer 220 may be formed in linear wiring shapes on the base substrate 210 made of an insulating material. Alternatively, the first circuit wiring layer 220 may be formed in a coil shape wound spirally on the base substrate 210. In the former case, the multilayer substrate of the present disclosure may be provided as a flexible circuit board. In the latter case, the multilayer substrate of the present disclosure may be provided as a coil substrate.

The first circuit wiring layer 220 may be formed by a photolithography method. However, the present disclosure is not limited thereto, and the first circuit wiring layer 220 may also be formed by various processes such as printing, bonding, coating, or plating. The first circuit wiring layer 220 may be formed to have a thickness of 5 μm to 200 μm. Preferably, the first circuit wiring layer 220 may be formed to have a thickness of 30 μm to 100 μm. More preferably, the first circuit wiring layer 220 may be formed to have a thickness of 40 μm to 80 μm.

Referring again to FIG. 1, the following description will be provided.

After forming the first circuit wiring layer 220 and the first via pad 230 on the base substrate 210, an interlayer insulating layer 240 is formed to cover the first circuit wiring layer 220 and the first via pad 230 (S120). The interlayer insulating layer 240 may be formed by various methods such as lamination or hot pressing.

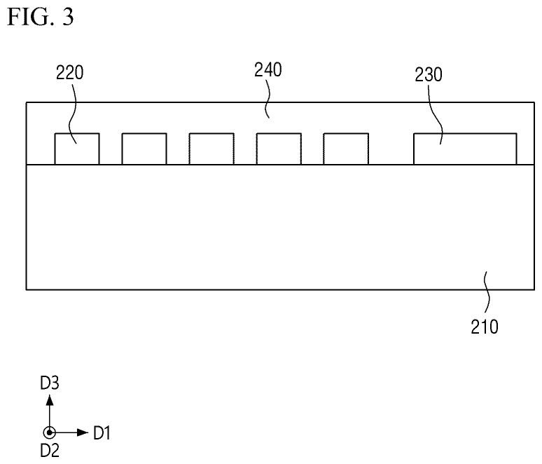

FIG. 3 is an exemplary view illustrating step S120 of the method of manufacturing a multilayer substrate according to an embodiment of the present disclosure. Referring to FIG. 3, the interlayer insulating layer 240 may be formed to cover an upper surface and side surfaces of the first circuit wiring layer 220, an upper surface and side surfaces of the first via pad 230, and portions of the base substrate 210 on which the first circuit wiring layer 220 and the first via pad 230 are not formed. However, the present disclosure is not limited thereto, and the interlayer insulating layer 240 may be formed to selectively cover some regions as necessary. For example, the interlayer insulating layer 240 may be formed to cover only the first circuit wiring layer 220 and the first via pad 230.

Referring again to FIG. 1, the following description will be provided.

After forming the interlayer insulating layer 240 on the base substrate 210, a main via is processed and formed in the interlayer insulating layer 240 (S130).

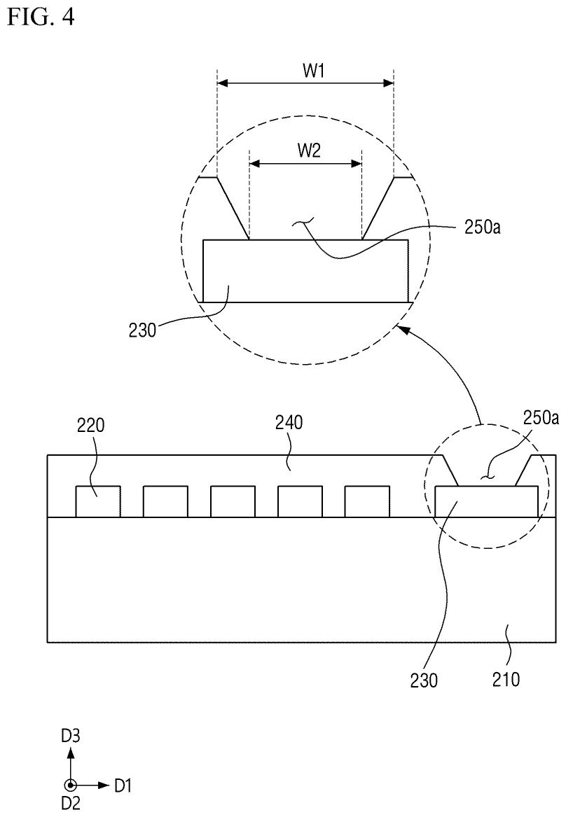

FIG. 4 is an exemplary view illustrating step S130 of the method of manufacturing a multilayer substrate according to an embodiment of the present disclosure. Referring to FIG. 4, a main via 250a may be formed to penetrate the interlayer insulating layer 240 in a thickness direction D3 from an upper surface of the interlayer insulating layer 240 and contact the first via pad 230. The main via 250a may be formed to have a size corresponding to the first via pad 230. For example, the main via 250a may be formed to have the same size as the first via pad 230. Alternatively, the main via 250a may be formed to have a size smaller than that of the first via pad 230.

The main via 250a may be formed using a laser drill. In this case, the main via 250a may be formed using a UV laser. Alternatively, the main via 250a may be formed using a CO₂ laser.

A lower diameter of the main via 250a may be formed to have a width different from a width of an upper diameter thereof. Specifically, the lower diameter of the main via 250a may be formed to be narrower than the upper diameter thereof. A width W2 of the lower diameter may be formed to have a value of 75% or more and less than 100% relative to a width W1 of the upper diameter (0.75×W1≤W2<1×W1). However, the present disclosure is not limited thereto, and the width W2 of the lower diameter may also be formed to be 75% or less of the width W1 of the upper diameter. When the width W2 of the lower diameter is formed to be 75% or less of the width W1 of the upper diameter, the width W2 of the lower diameter may be selected as an appropriate value according to a size of the upper diameter. Meanwhile, the lower diameter of the main via 250a may also be formed to have the same width as the upper diameter thereof.

Referring again to FIG. 1, the following description will be provided.

After forming the main via 250a in the interlayer insulating layer 240, a sub-via is processed and formed in an edge region of the main via 250a (S140).

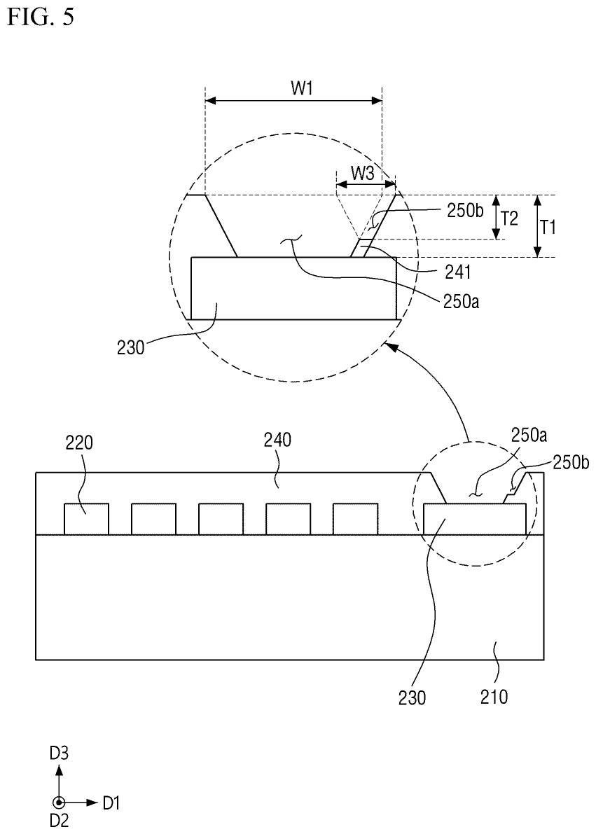

FIG. 5 is an exemplary view illustrating step S140 of the method of manufacturing a multilayer substrate according to an embodiment of the present disclosure. Referring to FIG. 5, a sub-via 250b may be formed such that a portion thereof overlaps the main via 250a. In the following description, the main via 250a and the sub-via 250b are collectively defined as a via portion 250.

The sub-via 250b may be formed to have the same shape as the main via 250a. However, the present disclosure is not limited thereto, and the sub-via 250b may also be formed to have a shape different from that of the main via 250a. Planar shapes of the main via 250a and the sub-via 250b may be selected from polygonal shapes such as triangular or quadrangular shapes, circular shapes, elliptical shapes, and linear shapes.

A thickness T2 of the sub-via 250b may be smaller than a thickness T1 of the main via 250a. Accordingly, after the sub-via 250b is processed and formed, the interlayer insulating layer 240 may remain under the sub-via 250b without being etched. For example, a residual insulating layer 241 remaining in the via portion 250 may be formed to be as thin as less than 5 μm.

An upper diameter of the sub-via 250b may be formed to have a width equal to or different from a width of the upper diameter of the main via 250a. A width W3 of the upper diameter of the sub-via 250b may be formed to have a value of 45% to 100% relative to the width W1 of the upper diameter of the main via 250 a (0.45×W1≤W3≤1.0×W1).

If the width W3 of the upper diameter of the sub-via 250b is formed to be less than 45% relative to the width W1 of the upper diameter of the main via 250a, an area of the residual insulating layer 241 remaining in the via portion 250 may become smaller than an appropriate value. In this case, in an etching process step, the residual insulating layer 241 may not be deformed toward an upper portion of the first via pad 230 in which an undercut is formed. Alternatively, even if the residual insulating layer 241 is deformed, it may not be bonded to the upper portion of the first via pad 230 in which an undercut is formed.

If the width W3 of the upper diameter of the sub-via 250b exceeds 100% relative to the width W1 of the upper diameter of the main via 250a, the area of the residual insulating layer 241 remaining in the via portion 250 may become larger than an appropriate value. In this case, in an etching process step, the residual insulating layer 241 may remain in a state having strong durability against an etching solution and may not be deformed toward an upper portion of the first via pad 230 in which an undercut is formed. That is, an undercut structure may persist within the via portion 250, and a void problem caused by the undercut structure cannot be resolved.

An upper area of the residual insulating layer 241 may be formed to be 1% to 30% of a lower area of the main via 250a. Preferably, the upper area of the residual insulating layer 241 may be formed to be 5% to 20% of the lower area of the main via 250a. More preferably, the upper area of the residual insulating layer 241 may be formed to be 9% to 15% of the lower area of the main via 250a.

If the upper area of the residual insulating layer 241 is less than 1%, the area of the residual insulating layer 241 may become smaller than an appropriate value. In this case, in an etching process step, the residual insulating layer 241 may not be deformed toward the upper portion of the first via pad 230 in which an undercut is formed. Alternatively, even if the residual insulating layer 241 is deformed, it may not be bonded to the upper portion of the first via pad 230 in which an undercut is formed.

If the upper area of the residual insulating layer 241 exceeds 30%, the area of the residual insulating layer 241 may become larger than an appropriate value. In this case, in an etching process step, the residual insulating layer 241 may remain in a state of strong durability against an etching solution and may not be deformed toward the upper portion of the first via pad 230 in which an undercut is formed. That is, the undercut structure may persist within the via portion 250, and a void problem caused by the undercut structure cannot be resolved.

Referring again to FIG. 1, the following description will be provided.

After sequentially forming the main via 250a and the sub-via 250b in the interlayer insulating layer 240, an etching process is performed (S150) for surface cleaning or modification of a surface on which a base layer described in step S160 is to be formed. Alternatively, a desmear process may be performed.

A surface of the first via pad 230 exposed to the outside may be etched to a thickness of 1 μm or more and 5 μm or less from below the interlayer insulating layer 240 in the etching process or the desmear process. At this time, an undercut may occur in which etching extends to a portion of the interlayer insulating layer 240 adjacent to a lower boundary of the main via 250a.

If etching is performed to less than 1 μm, a distribution of a homogeneous metal region inside the via portion 250 may be insufficient, and thus, an interface reliability problem caused by formation of a dissimilar metal layer may occur. If etching exceeds 5 μm, an undercut structure may additionally occur, and bonding between the interlayer insulating layer 240 and the first via pad 230 may become difficult. In addition, when the etching process is performed, durability or strength of the residual insulating layer 241 may be weakened by the etching solution, and thus, the residual insulating layer 241 may be deformed into a shape bonded to the upper portion of the first via pad 230 in which an undercut is formed.

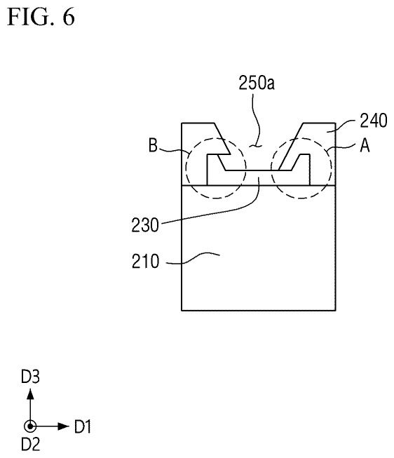

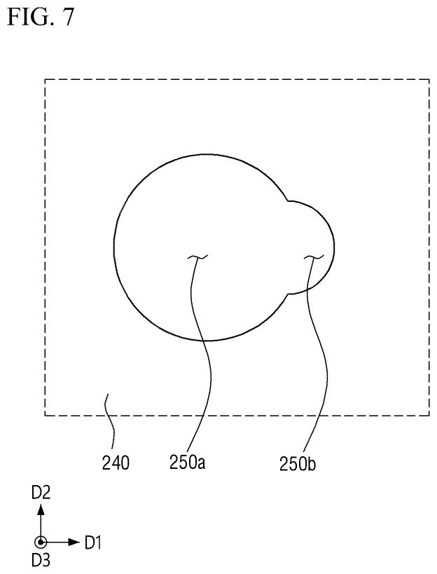

As a result, a vertical cross-section and a horizontal cross-section of the via portion 250 are as illustrated in FIGS. 6 and 7, respectively. FIG. 6 is a first exemplary view illustrating step S150 of the method of manufacturing a multilayer substrate according to an embodiment of the present disclosure. FIG. 7 is a second exemplary view illustrating step S150 of the method of manufacturing a multilayer substrate according to an embodiment of the present disclosure. Referring to FIGS. 6 and 7, the residual insulating layer 241 is bonded along a profile of an upper edge region of the first via pad 230 where an undercut occurs, and thus, one end of the residual insulating layer 241 is bonded to the upper portion of the first via pad 230 (see A). Meanwhile, in a region where the sub-via 250b is not formed, a lower portion of the residual insulating layer 241 and the upper portion of the first via pad 230 are spaced apart by a thickness of the undercut (see B). That is, both side cross-sections of the via portion 250 may be formed in an asymmetric structure.

The example of FIG. 7 illustrates a case in which a single sub-via 250b is formed around the main via 250a. However, the present disclosure is not limited thereto, and a plurality of sub-vias may also be formed around the main via 250a.

The plurality of sub-vias may be simultaneously formed when sub-vias are processed and formed in the edge region of the main via 250a. However, the present disclosure is not limited thereto, and the plurality of sub-vias may also be sequentially formed with time intervals therebetween.

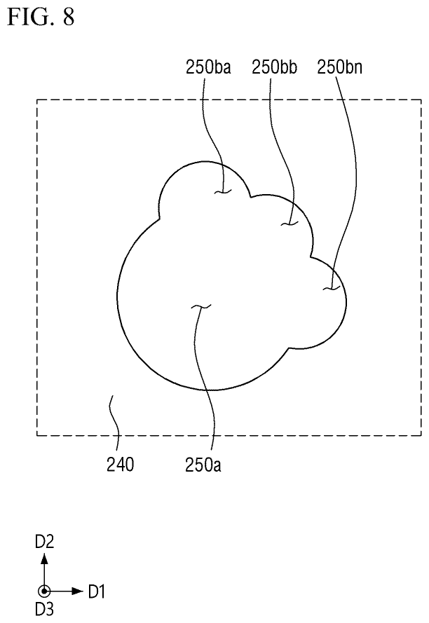

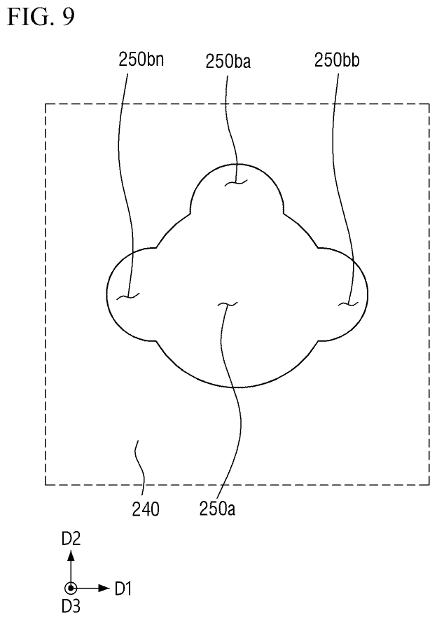

Referring to FIG. 8, a plurality of sub-vias 250ba, 250bb, . . . , 250bn may be formed along a circumference of the main via 250a in a partially overlapping manner. However, the present embodiment is not limited thereto. Referring to FIG. 9, the plurality of sub-vias 250ba, 250bb, . . . , 250bn may also be formed along the circumference of the main via 250a in a spaced-apart manner. FIG. 8 is a third exemplary view illustrating step S150 of the method of manufacturing a multilayer substrate according to an embodiment of the present disclosure. FIG. 9 is a fourth exemplary view illustrating step S150 of the method of manufacturing a multilayer substrate according to an embodiment of the present disclosure.

Referring again to FIG. 1, the following description will be provided.

When the etching process or the desmear process is completed, a base layer 260 is formed on an inner side of the via portion 250 and on upper and side surfaces of the interlayer insulating layer 240 (S160). The base layer 260 may be formed by a sputtering process, which is a dry conductive treatment, or by an electroless plating process, which is a wet conductive treatment. In this embodiment, a case in which the base layer 260 is formed using a sputtering process will be described as an example.

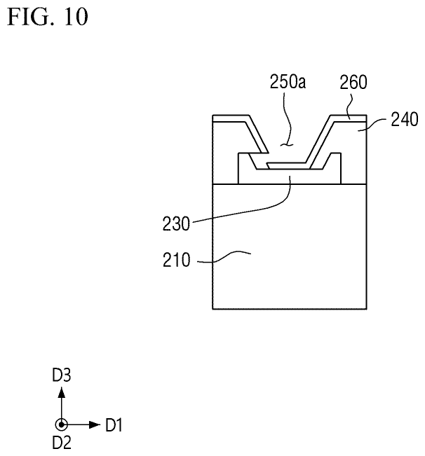

FIG. 10 is an exemplary view illustrating step S160 of the method of manufacturing a multilayer substrate according to an embodiment of the present disclosure. The first via pad 230 and the base layer 260 described above may be formed using metals. In the following description, a metal used to form the first via pad 230 is defined as a first metal, and a metal used to form the base layer 260 is defined as a second metal.

A base layer 260 may be formed to have a thickness of 20 nm to 30 nm. However, the base layer 260 of the present disclosure is not necessarily limited to being formed within the above thickness range. The base layer 260 may be formed in a structure in which some regions are not continuous but are cut off. The base layer 260 may be discontinuous in a portion where an undercut occurs between the interlayer insulating layer 240 and the first via pad 230.

The second metal used to form the base layer 260 may include at least one of Ni and Cr. However, the present disclosure is not limited thereto, and the second metal may be selected from, but not limited to, Cu, Ag, Ti, or the like in addition to Ni and Cr.

The first metal used to form the first via pad 230 may be different from the second metal. For example, the first metal may be Cu, and the second metal may be Ni/Cr. However, the present disclosure is not limited thereto, and the first metal may also be the same as the second metal. For example, the first metal and the second metal may both be Cu.

Referring again to FIG. 1, the following description will be provided.

After forming the base layer 260 on the via portion 250, the interlayer insulating layer 240, and the like, a resist pattern is formed on the interlayer insulating layer 240 (S170). The resist pattern may be formed on the interlayer insulating layer 240 to form a second circuit wiring layer, a second via pad, and the like on the interlayer insulating layer 240.

After forming the resist pattern on the interlayer insulating layer 240, plating is performed in spaces between such resist patterns and in the via portion 250 (S180). As a result of the plating, a second circuit wiring layer, a second via pad, and the like may be formed on the interlayer insulating layer 240.

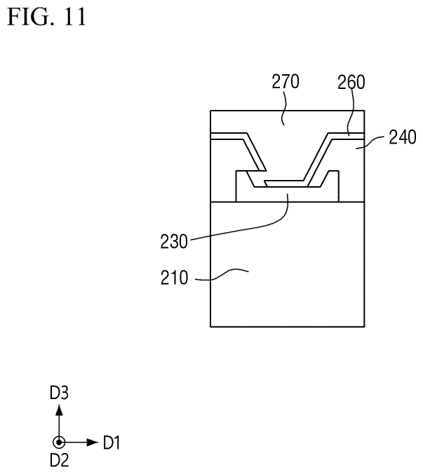

FIG. 11 is an exemplary view illustrating step S180 of the method of manufacturing a multilayer substrate according to an embodiment of the present disclosure. Referring to FIG. 11, a plating portion 270 filled in the via portion 250 by plating may have different thicknesses at both ends in contact with an inner side of the interlayer insulating layer 240, and may have an asymmetric structure in which both sides are different from each other with respect to a virtual central axis.

The base layer 260 is formed along an inner side surface where the first via pad 230 and the interlayer insulating layer 240 are in contact, and may serve as a lead-in wiring. In a conventional case, since a side surface of the interlayer insulating layer 240 and the first via pad 230 do not contact each other due to the undercut, the base layer 260 had a disconnected structure. Accordingly, current is not desirably applied through the base layer 260, and plating of the second via pad is completed before Cu is completely plated to an inner side of the undercut structure. As a result, a void occurs, and via interface reliability is degraded.

In contrast, in the present disclosure, an inner region in which the side surface of the interlayer insulating layer 240 and the first via pad 230 are bonded is generated, and the base layer 260 is formed along the side surface of the interlayer insulating layer 240 and may thus be continuous with the base layer 260 formed on an upper portion of the first via pad 230. Accordingly, a path through which current may be applied is formed, Cu is completely plated even to an inner side of a remaining undercut structure. Thus, void generation may be suppressed, and via interface reliability may also be improved.

Referring again to FIG. 1, the following description will be provided.

After plating is completed, the resist pattern is stripped from the interlayer insulating layer 240 (S190).

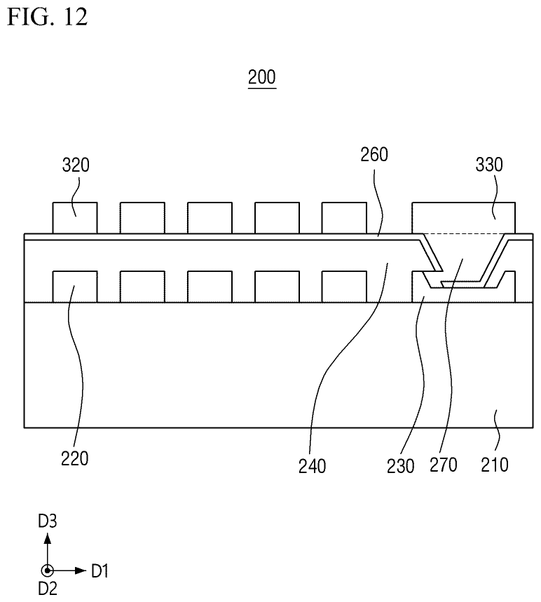

FIG. 12 is a first exemplary view illustrating step S190 of the method of manufacturing a multilayer substrate according to an embodiment of the present disclosure. When the resist pattern is stripped, a multilayer substrate 200 may be formed in a two-layer structure including the base substrate 210, the first circuit wiring layer 220, the first via pad 230, the interlayer insulating layer 240, the base layer 260, the plating portion 270, the second circuit wiring layer 320, and the second via pad 330.

The first circuit wiring layer 220 may be electrically connected to the first via pad 230 formed at the same level. Likewise, the second circuit wiring layer 320 may be electrically connected to the second via pad 330 formed at the same level. The first via pad 230 may be electrically connected to the second via pad 330 through the plating portion 270 filled in the via portion 250. Accordingly, the first circuit wiring layer 220 and the second circuit wiring layer 320 may be electrically connected through the first via pad 230, the plating portion 270, and the second via pad 330.

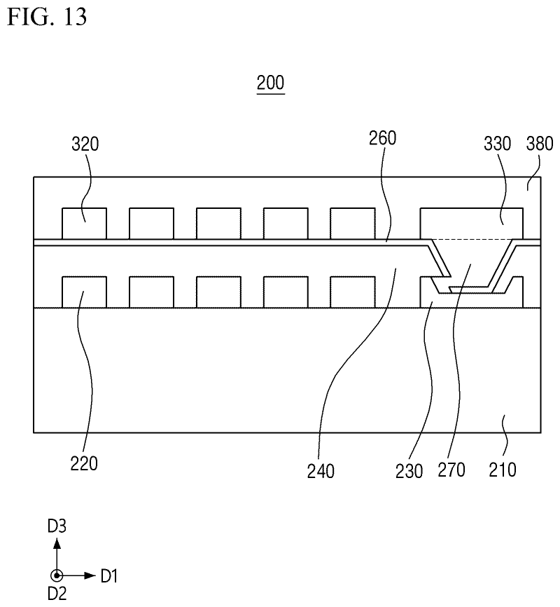

Referring to FIG. 13, when the multilayer substrate 200 is formed in a two-layer structure, the second circuit wiring layer 320 and the second via pad 330 may be covered by a protective layer 380 formed thereon. At this time, an external connection terminal may be exposed without being covered. FIG. 13 is a second exemplary view illustrating step S190 of the method of manufacturing a multilayer substrate according to an embodiment of the present disclosure.

The multilayer substrate 200 may also be formed in a structure of three or more layers. For example, when the multilayer substrate 200 is formed in a three-layer structure, an insulating layer, a via portion including a main via and a sub-via, a base layer, a resist pattern, a plating portion, a third circuit wiring layer, a third via pad, a protective layer, and the like may be sequentially formed on the second circuit wiring layer 320 and the second via pad 330. The insulating layer, the via portion, the base layer, the resist pattern, the plating portion, the third circuit wiring layer, the third via pad, the protective layer, and the like may be sequentially formed on the second circuit wiring layer 320 and the second via pad 330 according to the method described above with reference to FIGS. 1 to 13. Such a method may be repeatedly applied even when the multilayer substrate 200 is formed in a structure of four or more layers.

So far, a case in which a single main via 250a and a single sub-via 250b are formed on the first via pad 230 has been described with reference to FIGS. 1 to 13. In addition, a case in which a single main via 250a and a plurality of sub-vias 250ba, 250bb, . . . , 250bnare formed on the first via pad 230 has been described.

However, the present disclosure is not limited thereto, and a plurality of main vias and a single sub-via 250b may also be formed on the first via pad 230. Alternatively, a plurality of main vias and a plurality of sub-vias 250ba, 250bb, . . . , 250bn may also be formed on the first via pad 230. Hereinafter, these cases will be described.

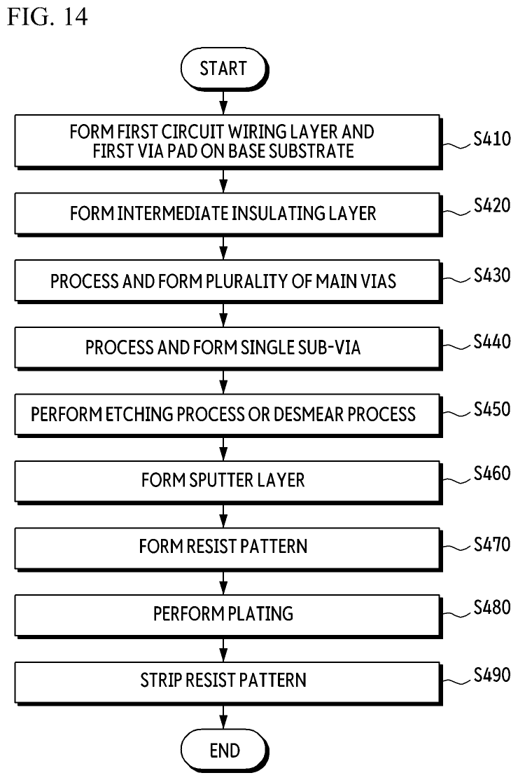

FIG. 14 is a flowchart illustrating a method of manufacturing a multilayer substrate according to another embodiment of the present disclosure. In the example of FIG. 14, a case in which two main vias and a single sub-via 250b are formed on the first via pad 230 will be described.

First, a first circuit wiring layer 220 and a first via pad 230 are formed on one surface of a base substrate 210 (S410). Step S410 may be performed in the same manner as step S110 described above, and thus, a detailed description thereof will be omitted.

Subsequently, an interlayer insulating layer 240 is formed to cover the first circuit wiring layer 220 and the first via pad 230 (S420). Step S420 may be performed in the same manner as step S120 described above, and thus, a detailed description thereof will be omitted.

Thereafter, two main vias, i.e., a first main via 250c and a second main via 250d, are processed and formed in the interlayer insulating layer 240 (S430).

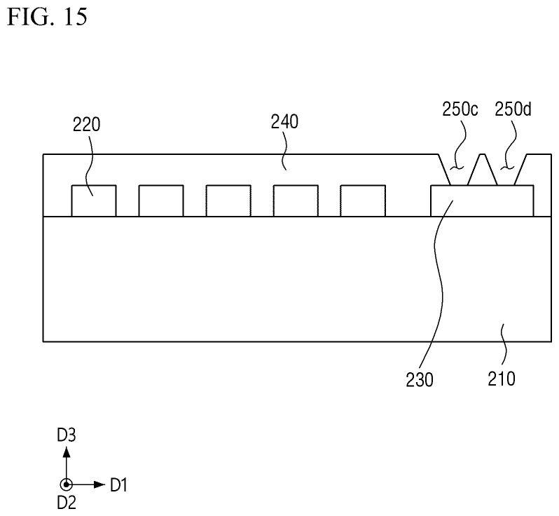

FIG. 15 is an exemplary view illustrating step S430 of the method of manufacturing a multilayer substrate according to another embodiment of the present disclosure. Referring to FIG. 15, the first main via 250c and the second main via 250d may be formed by the same processing method as the main via 250a described above. For example, the first main via 250c and the second main via 250d may be formed using a laser drill using a UV laser. Alternatively, the first main via 250c and the second main via 250d may be formed using a laser drill using a CO2 laser.

The first main via 250c and the second main via 250d may be formed to have the same shape as the above-described main via 250a. That is, the first main via 250c and the second main via 250d may be formed to have the same shape. For example, the first main via 250c and the second main via 250d may be formed such that lower diameters thereof have widths different from widths of upper diameters thereof. Alternatively, the lower diameters may be formed to have the same width as the upper diameters. However, the present disclosure is not limited thereto, and the first main via 250c and the second main via 250d may also be formed to have different shapes.

The first main via 250c and the second main via 250d may be formed to have the same size as the above-described main via 250a. That is, the first main via 250c and the second main via 250d may be formed to have the same size. In addition, the first main via 250c and the second main via 250d may be formed simultaneously. However, the present disclosure is not limited thereto, and the first main via 250c and the second main via 250d may also be formed sequentially.

The first main via 250c and the second main via 250d may be formed to be spaced apart from each other. A distance between the first main via 250c and the second main via 250d may preferably be 10 μm to 50 μm, but may be changed to various values depending on a size of the first via pad 230.

Meanwhile, when three or more main vias are formed on the first via pad 230, an n-th main via (where n is a natural number of 3 or greater) may be formed in the same manner as the first main via 250c or the second main via 250d.

Referring again to FIG. 14, the following description will be provided.

After forming the first main via 250c and the second main via 250d in the interlayer insulating layer 240, the sub-via 250b is processed and formed in a space between the first main via 250c and the second main via 250d (S440).

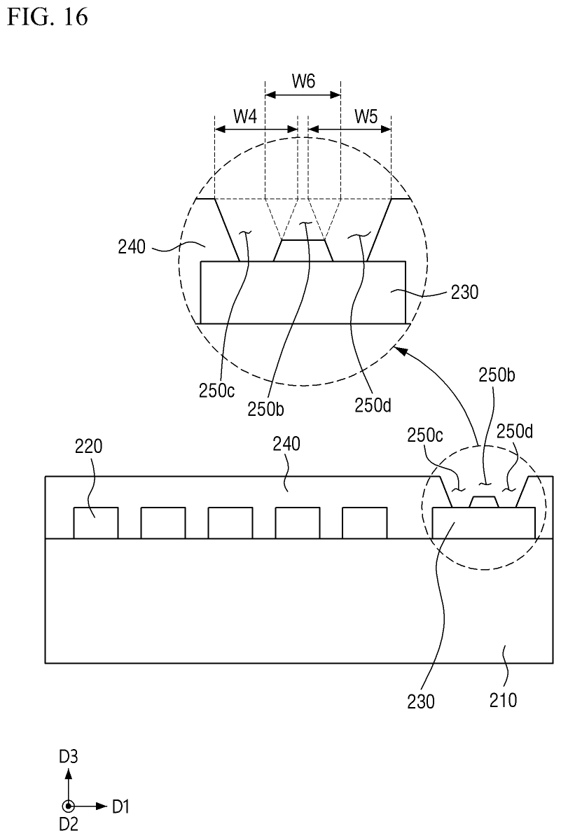

FIG. 16 is a first exemplary view illustrating step S440 of the method of manufacturing a multilayer substrate according to another embodiment of the present disclosure. Referring to FIG. 16, the sub-via 250b may be formed such that portions thereof overlap the first main via 250c and the second main via 250d. In the following description, the first main via 250c, the second main via 250d, and the sub-via 250b are collectively defined as a via portion 250.

Since a shape and size of the sub-via 250b and a level of a residual insulating layer 241 remaining in the via portion 250 according to the size of the sub-via 250b are the same as that described above with reference to FIG. 1, detailed descriptions thereof will be omitted.

An upper diameter of the sub-via 250b may be formed to have a width different from widths of the upper diameters of the first main via 250c and the second main via 250d. Specifically, the upper diameter of the sub-via 250b may be formed to be narrower than the upper diameters of the first main via 250c and the second main via 250d. A width W6 of the upper diameter of the sub-via 250b may be formed to be 40% to 80% relative to widths W4 and W5 of the upper diameters of the first main via 250c and the second main via 250d (0.4*W4, W5≤W6≤0.8*W4, W5).

When the width W6 of the upper diameter of the sub-via 250b is formed to be less than 40% relative to the widths W4 and W5 of the upper diameters of the first main via 250c and the second main via 250d, an area of the residual insulating layer 241 remaining in the via portion 250 may become smaller than an appropriate value. In this case, in an etching process step, the residual insulating layer 241 may not be deformed toward an upper portion of the first via pad 230 in which an undercut is formed. Alternatively, even if the residual insulating layer 241 is deformed, the residual insulating layer 241 may not be bonded to the upper portion of the first via pad 230 in which an undercut is formed.

When the width W6 exceeds 80% relative to the widths W4 and W5 of the upper diameters of the first main via 250c and the second main via 250d, bonding between the residual insulating layer 241 and the first via pad 230 may be possible, but productivity may be reduced.

The first main via 250c, the second main via 250d, and the sub-via 250b may overlap each other with an overlap area of 10% to 30% of a lower area of the first main via 250c. If the overlap area between the first main via 250c and the sub-via 250b and/or the overlap area between the second main via 250d and the sub-via 250b is less than 10%, the same problem as that described above when the overlap area between the main via 250a and the sub-via 250b is less than 1% may occur. Likewise, if the overlap area exceeds 30%, the same problem as that described above when the overlap area between the main via 250a and the sub-via 250b exceeds 30% may occur.

The sub-via 250b may be formed in various shapes such as circular, polygonal, or linear shapes. Depending on width, thickness, and area of the sub-via 250b, a lower central portion of the sub-via 250b may have a higher level of laser processing than other regions. Accordingly, an upper portion of the first via pad 230 corresponding to the lower central region of the sub-via 250b may be partially exposed, and an undercut structure may occur.

When forming the sub-via 250b, processing is performed by scanning a laser multiple times depending on an area or thickness of the sub-via 250b. In this case, processing is performed multiple times while changing a position of the laser, and thus, a region where such processing overlaps may occur. A higher laser processing level means that the region where processing overlaps is processed more deeply than other regions.

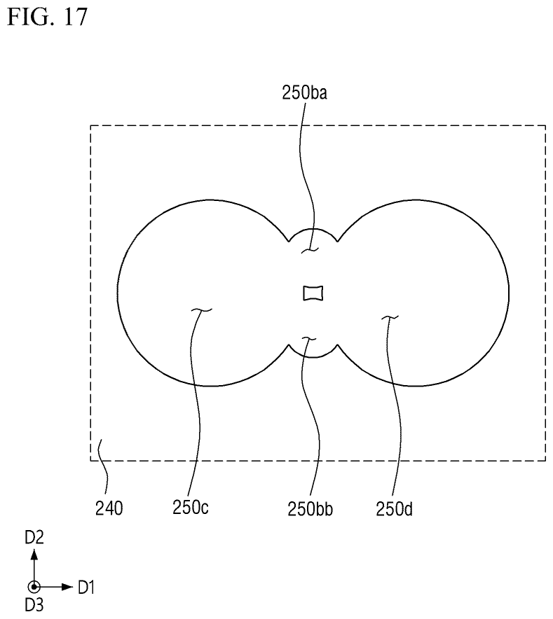

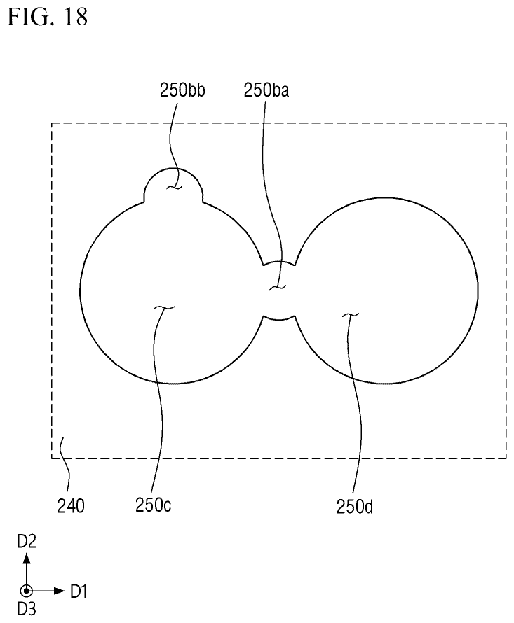

To address this problem, the sub-via 250b may be formed in a ring shape. Forming the sub-via 250b in a ring shape means forming the sub-via 250b so as to be connected to both the first main via 250c and the second main via 250d. That is, the sub-via 250b may be formed such that portions thereof overlap the first main via 250c and the second main via 250d. As will be described later, when the sub-via 250b is formed in a ring shape, the sub-via 250b may be formed like a first sub-via 250ba or a second sub-via 250bb of FIG. 17. Alternatively, the sub-via 250b may be formed like a first sub-via 250ba of FIG. 18. When the sub-via 250b is formed in a ring shape, the region (e.g., the lower central region of the sub-via 250b) where processing overlaps may be minimized, and exposure of the upper portion of the first via pad 230 may be controlled.

Referring again to FIG. 14, the following description will be provided.

After sequentially forming the first main via 250c, the second main via 250d, and the sub-via 250b in the interlayer insulating layer 240, an etching process is performed (S450) for surface cleaning or modification of a surface on which a base layer 260 described below in step S460 is to be formed. Alternatively, a desmear process may be performed instead of the etching process. Step S450 may be performed in the same manner as step S150 described above, and thus, a detailed description thereof will be omitted.

After completing the etching process or the desmear process, the base layer 260 is formed on an inner side of the via portion 250 and on upper and side surfaces of the interlayer insulating layer 240 (S460). Step S460 may be performed in the same manner as step S160 described above, and thus, a detailed description thereof will be omitted.

After forming the base layer 260 on the via portion 250 and the interlayer insulating layer 240, a resist pattern is formed on the interlayer insulating layer 240 (S470). Step S470 may be performed in the same manner as step S170 described above, and thus, a detailed description thereof will be omitted.

After forming the resist pattern on the interlayer insulating layer 240, plating is performed in spaces between such resist patterns and in the via portion 250 (S480). Step S480 may be performed in the same manner as step S180 described above, and thus, a detailed description thereof will be omitted.

After plating is completed, the resist pattern is stripped from the interlayer insulating layer 240 (S490). Step S490 may be performed in the same manner as step S190 described above, and thus, a detailed description thereof will be omitted.

As described above, a plurality of main vias and a plurality of sub-vias may be formed on the first via pad 230. In this case, each of the plurality of sub-vias may overlap the plurality of main vias. For example, referring to FIG. 17, portions of the first sub-via 250ba and the second sub-via 250bb may each overlap the first main via 250c and the second main via 250d. FIG. 17 is a second exemplary view illustrating step S440 of the method of manufacturing a multilayer substrate according to another embodiment of the present disclosure.

However, the present disclosure is not limited thereto, and among the plurality of sub-vias, some sub-vias may overlap the plurality of main vias while other sub-vias may not overlap the plurality of main vias. For example, referring to FIG. 18, a portion of the first sub-via 250ba may overlap both the first main via 250c and the second main via 250d, whereas a portion of the second sub-via 250bb may overlap only the first main via 250c. FIG. 18 is a third exemplary view illustrating step S440 of the method of manufacturing a multilayer substrate according to another embodiment of the present disclosure.

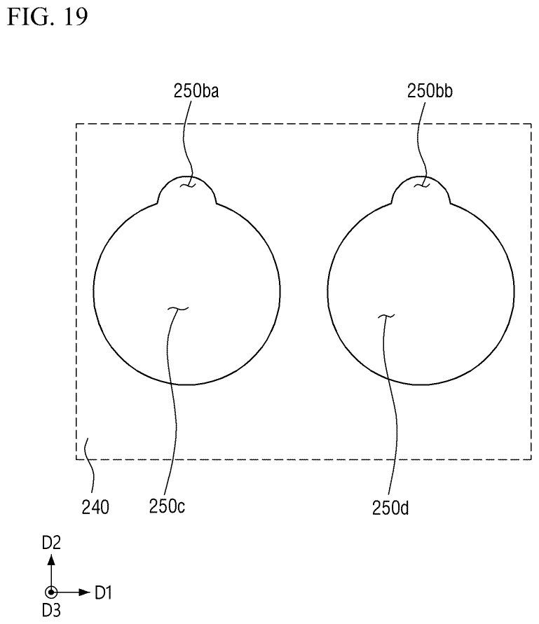

Alternatively, the plurality of sub-vias may not overlap the plurality of main vias. For example, referring to FIG. 19, a portion of the first sub-via 250ba may overlap only the first main via 250c, and a portion of the second sub-via 250bb may overlap only the second main via 250d. FIG. 19 is a fourth exemplary view illustrating step S440 of the method of manufacturing a multilayer substrate according to another embodiment of the present disclosure.

So far, methods of manufacturing a multilayer substrate according to various embodiments of the present disclosure have been described with reference to FIGS. 1 to 19. Hereinafter, the method of manufacturing a multilayer substrate described in the background art will be defined as a conventional technique, the method of manufacturing a multilayer substrate described with reference to FIG. 1 will be defined as a first embodiment, and the method of manufacturing a multilayer substrate described with reference to FIG. 14 will be defined as a second embodiment.

To verify effects of the present disclosure, a comparative experiment of via interface reliability was conducted using a bending test and a thermal cycle test. First, experimental conditions of the bending test are as follows.
Test scale: 400 g
Test point: additional analysis position
Number of bends: 100 (one repetition of 90° in a left/right axis is counted as one cycle)
Film fixing jig R value: 0.5 mm
One repetition of 90° in a left/right axis=1 count (180°)

Next, experimental conditions of the thermal cycle test are as follows.
Temperature: −40° C. to 125° C./20 min
Cycle: 50 times

According to results of the bending test and the thermal cycle test, interface separation occurred in the conventional technique, whereas no interface separation occurred in the first embodiment and the second embodiment. Accordingly, the present disclosure may achieve an effect of improving via interface reliability compared with the conventional technique.

As described above, the multilayer substrate 200 of the present disclosure may be provided as a flexible circuit board or a coil substrate. When the multilayer substrate 200 is provided as a flexible circuit board, an electronic device may include the multilayer substrate 200 and a semiconductor chip mounted on the multilayer substrate 200. When the multilayer substrate 200 is provided as a coil substrate, an electronic device may include the multilayer substrate 200 and may be used in fields that require electromagnetic force.

Although embodiments of the present disclosure have been described above with reference to the accompanying drawings, the present disclosure is not limited to the embodiments described above and may be manufactured in various different forms. One of ordinary skill in the art will understand that the present disclosure may be implemented in other specific forms without changing the technical concept or characteristics of the present disclosure. Accordingly, the embodiments described above should be understood as illustrative in all respects and not limiting.

### INDUSTRIAL APPLICABILITY

The present disclosure relates to a multilayer substrate. The present disclosure may be applied to a flexible circuit board or a coil substrate.

What is claimed is:

1. A multilayer substrate comprising:
a base substrate;
a first circuit wiring layer and a first via pad formed on the base substrate;
an interlayer insulating layer covering the first circuit wiring layer and the first via pad;
a via portion formed to penetrate the interlayer insulating layer and contact the first via pad;
a plating portion filling the via portion;
a second circuit wiring layer formed on the interlayer insulating layer; and
a second via pad formed on the plating portion,
wherein the via portion includes a main via and a sub-via partially overlapping the main via.

2. The multilayer substrate of claim 1, wherein a lower diameter of the main via is smaller than an upper diameter of the main via.

3. The multilayer substrate of claim 1, wherein a depth of the sub-via is shallower than a depth of the main via.

4. The multilayer substrate of claim 1, wherein an upper diameter of the sub-via is smaller than an upper diameter of the main via.

5. The multilayer substrate of claim 1, wherein a plurality of main vias are formed.

6. The multilayer substrate of claim 5, wherein the plurality of main vias are spaced apart from each other.

7. The multilayer substrate of claim 5, wherein the sub-via partially overlaps the plurality of main vias.

8. The multilayer substrate of claim 1, wherein the sub-via is formed in a ring shape with respect to the main via.

9. The multilayer substrate of claim 5, wherein a plurality of sub-vias are formed.

10. The multilayer substrate of claim 9, wherein each of the plurality of sub-vias partially overlaps the plurality of main vias.

11. The multilayer substrate of claim 9, wherein at least one of the plurality of sub-vias partially overlaps the plurality of main vias.

12. The multilayer substrate of claim 1, further comprising:
a base layer formed between the main via and the plating portion and between the sub-via and the plating portion.

13. The multilayer substrate of claim 12, wherein the base layer includes a discontinuous portion.

14. The multilayer substrate of claim 12, wherein:
the first via pad includes a first metal; and
the base layer includes a second metal.

15. An electronic device comprising the multilayer substrate of claim 1.

16. A method of manufacturing a multilayer substrate, the method comprising:
forming a first circuit wiring layer and a first via pad on a base substrate;
forming an interlayer insulating layer to cover the first circuit wiring layer and the first via pad;
forming a main via to penetrate a surface of the interlayer insulating layer and contact the first via pad;
forming a sub-via partially overlapping the main via;
performing an etching process or a desmear process on the main via and the sub-via;
forming a base layer to cover the interlayer insulating layer, the main via, and the sub-via; and
forming a plating portion in the main via and forming a second circuit wiring layer and a second via pad on the interlayer insulating layer and the plating portion.

17. The method of claim 16, wherein forming the sub-via comprises forming the sub-via to have a depth shallower than a depth of the main via such that an interlayer insulating layer remains under a portion of the sub-via that does not overlap the main via.

18. The method of claim 16, wherein performing the etching process or the desmear process comprises: etching a surface of the first via pad exposed under the main via; and forming the sub-via to have a depth shallower than a depth of the main via such that an interlayer insulating layer remains under a portion of the sub-via that does not overlap the main via.

19. The method of claim 16, further comprising:
forming a base layer covering the interlayer insulating layer, the main via, and the sub-via after performing the etching process or the desmear process.

20. The method of claim 16, further comprising:
forming a resist pattern on the base layer before forming the plating portion, the second circuit wiring layer, and the second via pad; and
stripping the resist pattern after forming the plating portion, the second circuit wiring layer, and the second via pad.
